(19) United States
(12) Patent Application Publication
(10) Pub. No.: US 2026/0237961 A1
(43) Pub. Date: Aug. 13, 2026

(54) LASER DEVICE, PHOTONIC CIRCUIT, AND PHOTONIC ASSEMBLY

(71) Applicant: ams-OSRAM International GmbH, Regensburg (DE)

(72) Inventor: Laura KREINER, Regensburg (DE)

(73) Assignee: ams-OSRAM International GmbH, Regensburg (DE)

(21) Appl. No.: 19/155,838

(22) PCT Filed: Jan. 26, 2024
(86) PCT No.: PCT/EP2024/051973

§ 371 Date: Aug. 12, 2025

(30) Foreign Application Priority Data
Feb. 17, 2023 (DE) 10 2023 103 983.0

(51) Int. Cl. H01S 5/02255; H01S 5/02251; H01S 5/22

(52) U.S. Cl. CPC H01S 5/02255; H01S 5/02251; H01S 5/22

(57) ABSTRACT

A laser device includes a body which has an edge-emitting laser in a first part. The first part is structured on the exit side of electromagnetic radiation, thereby forming a vertical lateral wall, and the laser device has a reflector on the lateral wall. The body has a diagonal reflective surface in a second part, said surface intersecting a vertical direction and a horizontal plane. The diagonal reflective surface is suitable for reflecting radiation emitted from the edge-emitting laser in a direction which intersects the horizontal plane. The first and the second part are mutually spaced.

### CROSS-REFERENCE TO RELATED APPLICATIONS

The present application is a national stage entry from International Application No. PCT/EP2024/051973, filed on Jan. 26, 2024, published as International Publication No. WO 2024/170258 A1 on Aug. 22, 2024, and claims priority to German Patent Application No. 10 2023 103 983.0, filed Feb. 17, 2023, the disclosures of all of which are hereby incorporated by reference in their entireties.

### BACKGROUND

Photonic circuits or photonic integrated circuits (PIC) usually include a light source and a plurality of optical elements, which are connected to one another via waveguides, for example. Photonic circuits are widely used in a plurality of applications.

In general, efforts are made to provide photonic circuits that are as compact as possible.

It is an object of the present disclosure to provide an improved laser device, an improved photonic circuit, and an improved photonic arrangement.

### SUMMARY

According to embodiments, the object is achieved by the subject matter of the independent claims. Further developments are defined in the dependent claims.

A laser device comprises a body comprising an edge emitting laser in a first part, the first part being patterned to form a vertical sidewall on an exit side of electromagnetic radiation, and the laser device comprising a reflector on the sidewall. The body comprises, in a second part, an slanted reflective surface intersecting a vertical direction and a horizontal plane. The slanted reflective surface is configured to reflect radiation emitted by the edge emitting laser in a direction intersecting the horizontal plane. The first and second parts are spaced apart from each other.

For example, the body comprises, in the second part, a plurality of mutually parallel oblique reflective surfaces. For example, the body comprises, in the second part, a plurality of mutually parallel oblique ridges each having the reflective surfaces. For example, a gap between adjacent parallel oblique ridges is not filled with a material, but unfilled. According to embodiments, for a distance d between the plurality of mutually parallel oblique reflective surfaces, the following relationship holds:

$$0.7 * λ \leq d \leq 1.3 * λ ,$$

wherein λ is the wavelength of the laser radiation emitted by the edge emitting laser.

For example, the laser device further comprises a reflective material on the slanted reflective surface facing the edge emitting laser.

According to embodiments, an inclination angle of the slanted reflective surface is selected according to an emission angle of the emitted laser radiation.

For example, the body may be a semiconductor body, and the first part may comprise a layer structure of an edge emitting semiconductor laser.

For example, the semiconductor body may comprise a substrate and a first semiconductor layer of a first conductivity type, an active zone and a second semiconductor layer of a second conductivity type in the first part. The first semiconductor layer, the active zone and the second semiconductor layer may be arranged on top of each other on the substrate to form a semiconductor layer stack.

For example, the reflector may comprise a dielectric mirror.

According to embodiments, a photonic circuit comprises a waveguide, a coupling device and the laser device as described above. The laser device is arranged vertically spaced apart from the waveguide and is configured to radiate electromagnetic radiation into the waveguide via the coupling device.

For example, the photonic circuit may further comprise a circuit substrate, wherein the body is arranged vertically spaced apart from the circuit substrate and the waveguide is arranged in or on the circuit substrate.

The photonic circuit may further comprise contact regions for electrically contacting the laser device, wherein the contact regions are arranged in or on the circuit substrate.

According to further embodiments, a photonic arrangement comprises an optical fiber, a coupling device and the laser device as described above. The laser device is arranged vertically spaced apart from the optical fiber and is configured to radiate electromagnetic radiation into the optical fiber via the coupling device.

The accompanying drawings serve to understand embodiments of the invention. The drawings illustrate embodiments and together with the description serve to explain the same. Further embodiments and numerous of the intended advantages result directly from the following detailed description. The elements and structures shown in the drawings are not necessarily illustrated true to scale with respect to one another. Identical reference signs refer to identical or corresponding elements and structures.

### BRIEF DESCRIPTION OF THE DRAWINGS

FIG. 1A shows a schematic cross-sectional view of a photonic circuit according to embodiments.

FIG. 1B shows an enlarged view of a part of a laser device according to embodiments.

FIG. 1C shows a schematic cross-sectional view of a part of a laser device according to embodiments.

FIG. 2 illustrates components of a laser device according to embodiments.

FIG. 3 shows a schematic top view of a photonic circuit according to embodiments.

### DETAILED DESCRIPTION

In the following detailed description, reference is made to the accompanying drawings, which form a part of the disclosure and in which specific embodiments are shown for illustrative purposes. In this context, directional terminology such as “top”, “bottom”, “front”, “back”, “over”, “on”, “leading”, “trailing”, “front”, “rear”, etc. refers to the orientation of the figures being described. Since the components of the embodiments can be positioned in different orientations, the directional terminology serves only for explanation and is in no way limiting.

The description of the embodiments is not limiting since other embodiments also exist and structural or logical changes can be made without deviating from the range defined by the patent claims. In particular, elements of embodiments described below can be combined with elements of others of the described embodiments, unless the context indicates otherwise.

The terms “wafer” or “semiconductor substrate” used in the following description can comprise any semiconductor-based structure having a semiconductor surface. Wafer and structure are understood to include doped and undoped semiconductors, epitaxial semiconductor layers, optionally supported by a base sup-port, and further semiconductor structures. For example, a layer of a first semiconductor material can be grown on a growth substrate of a second semiconductor material, for example a GaAs substrate, a GaN substrate or a Si substrate, or of an insulating material, for example on a sapphire substrate.

Depending on the intended use, the semiconductor can be based on a direct or an indirect semiconductor material. Examples of semiconductor materials particularly suitable for generating electromagnetic radiation comprise, in particular, nitride semiconductor compounds by which, for example, ultraviolet, blue or longer-wave light can be generated, such as, for example, GaN, InGaN, AlN, AlGaN, AlGaInN, AlGaInBN, phosphide semiconductor compounds by which, for example, green or longer-wave light can be generated, such as, for example, GaAsP, AlGaInP, GaP, AlGaP, as well as further semiconductor materials such as GaAs, AlGaAs, InGaAs, AlInGaAs, SiC, ZnSe, Zno, Ga₂ O₃, diamond, hexagonal BN and combinations of said materials. The stoichiometric ratio of the compound semiconductor materials can vary. Further examples of semiconductor materials can comprise silicon, silicon-germanium and germanium. In the context of the present description, the term “semiconductor” also includes organic semiconductor materials.

The term “substrate” generally comprises insulating, conductive or semiconductor substrates.

The term “vertical” as used in this description is intended to describe an orientation which is substantially perpendicular to the first surface of a substrate or semiconductor body. The vertical direction can correspond, for example, to a growth direction when growing layers.

The terms “lateral” and “horizontal” as used in this description are intended to describe an orientation or orientation which is substantially parallel to a first surface of a substrate or semiconductor body. This can be, for example, the surface of a wafer or a chip (die).

The horizontal direction can lie, for example, in a plane perpendicular to a growth direction when growing layers.

To the extent that the terms “have”, “contain”, “comprise”, “include” and the like are used here, these are open terms which indicate the presence of said elements or features, but do not exclude the presence of further elements or features. The in-definite articles and the specific articles comprise both the plural and the singular, unless the context clearly indicates otherwise.

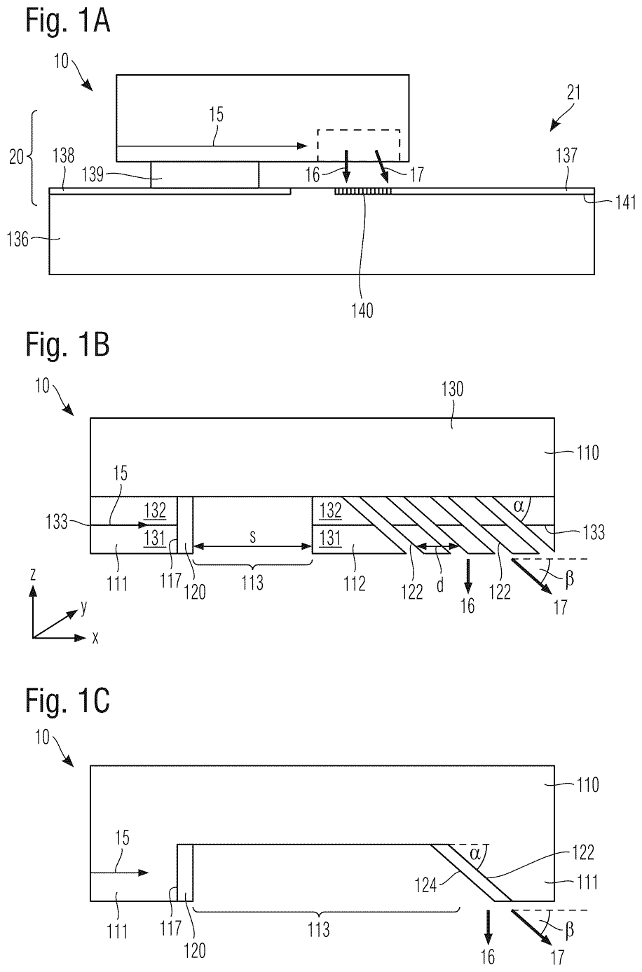

FIG. 1A shows a schematic cross-sectional view of a photonic circuit 20 according to embodiments. The photonic circuit 20 comprises, for example, a circuit substrate 136 and a waveguide 137 arranged above or in the circuit substrate 136. For example, the circuit substrate 136 can contain a semiconductor material, for example silicon. The waveguide 137 can contain a suitable waveguide material, for example Si₃N₄ or others. A laser device is arranged vertically spaced apart from the waveguide 137. For example, electrical contact regions 138 for supplying electrical current can be arranged in or on the circuit substrate 136. The contact regions 138 can be electrically connected to the laser device 10 via bond pads 139, for example. In this way, electrical driving of the laser device 10 can take place via the circuit substrate 136. The laser device 10 can be configured to emit laser radiation 15 which, as will be explained below, is deflected in the direction of the waveguide 137. For example, depending on the implementation of the laser device 10, first radiation 16 or second radiation 17 can be emitted in the direction of the waveguide 137. The laser radiation can be coupled into the waveguide 137 via a coupling device, for example a grating coupler 140.

According to further embodiments, which are likewise illustrated in FIG. 1A, a photonic arrangement 11 comprises the laser device 10, the coupling device, and an optical fiber 141. The reflected laser radiation 16, 17 can be coupled into the optical fiber 141 via the coupling device, for example the grating coupler 140.

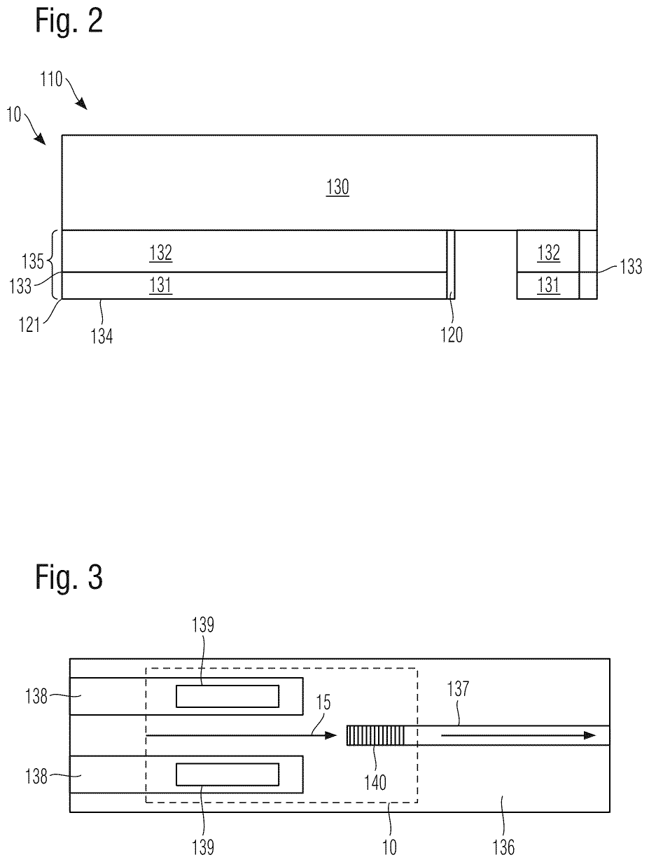

The edge emitting laser 115 can be implemented in any desired manner. For example, the edge emitting laser 115 can be a semiconductor laser, as will be described in more detail below under FIG. 2. However, according to further embodiments, the edge emitting laser 115 can also be a solid-state laser.

FIG. 1B shows an enlarged cross-sectional view of a part of the laser device 10 according to embodiments. The laser device 10 comprises a body 110 comprising an edge emitting laser 115 in a first part 111. The first part 111 is patterned to form a vertical sidewall 117 on an exit side of electromagnetic radiation 15. For example, the vertical sidewall 117 can be etched along a crystal direction and therefore have a high reflectivity. The laser device 10 comprises a reflector 120 on the vertical sidewall 117. The body 110 comprises, in a second part 112, a slanted reflective surface 122. The slanted reflective surface 122 intersects both a vertical direction (for example, the z-direction) and a horizontal plane (for example, the x-y-plane). Here, the slanted reflective surface 122 is configured to reflect radiation 15 emitted by the edge emitting laser 115 in a direction intersecting the horizontal plane, for example, the x-y-plane. Here, the first part 111 and the second part 112 are spaced apart from each other. For example, the first and second parts 111, 112 can be spaced apart from each other by a gap 113, wherein the gap 113 can have a length s, for example, measured in the x-direction. For example, the length s can be greater than 10 nm, for example, greater than a few 10 nm. For example, the length s can be less than 10 μm or less than a few μm.

The body 110 may comprise, for example, one or more semiconductor materials. For example, the material of the body 110 may be selected depending on the embodiment of the edge emitting laser 115. For example, when the edge emitting laser is embodied as a semiconductor laser, the body can contain a semiconductor material of the semiconductor laser, for example a growth substrate or silicon.

As shown in FIG. 1B, the laser radiation is emitted, for example, as first laser radiation 16 or as second laser radiation 17. The emission direction can depend on the exact dimensioning of the individual components of the second part 112. As illustrated in FIG. 1B, a plurality of slanted reflective surfaces 122 can be arranged in the second part 112 of the laser device. The slanted reflective surfaces 122 can be arranged, for example, at an identical distance d. The slanted reflective surfaces 122 can each be formed parallel to one another. An angle α of the slanted reflective surfaces 122 to a horizontal plane can be selected according to a desired emission angle β. The distance d between the plurality of mutually parallel oblique reflective surfaces 122 can satisfy the following relationship: 0.7*λ≤d≤1.3*λ. In this case, A corresponds to the wavelength of the laser radiation 15 emitted by the edge emitting laser 115. In this way, grating effects occur, by which specific emission angles β can be set. For example, a plurality of oblique parallel ridges having slanted reflective surfaces are formed in the second part 112 of the laser device.

For example, such oblique reflective gratings can be etched by an ion beam etching method, in which the body 110 is covered with a suitable mask layer and the body 110 is arranged tilted with respect to the ion beam source. The etching angle of the reflective surfaces thus results from the inclination angle of the body 110 with respect to the ion beam source.

The reflector 120 can be implemented, for example, as a dielectric mirror.

In general, the term “dielectric mirror” comprises any arrangement that reflects incident electromagnetic radiation to a large degree (for example >90%) and is non-conductive. For example, a dielectric mirror layer can be formed by a sequence of very thin dielectric layers each having different refractive indices. For example, the layers can alternately have a high refractive index (n>n₀) and a low refractive index (n<n₀) and be formed as a Bragg reflector. The average refractive index n₀ depends on the materials used and can be, for example, approximately 1.7. For example, the layer thickness can be λ/4, wherein λ indicates the wavelength of the light to be reflected in the respective medium. The layer viewed from the incident light can have a larger layer thickness, for example 3λ/4. Due to the small layer thickness and the difference of the respective refractive indices, the dielectric mirror layer provides a high reflectivity and is non-conductive at the same time. The dielectric mirror layer is thus suitable for insulating components of the semiconductor device from each other. A dielectric mirror layer can comprise, for example, 2 to 50 dielectric layers. A typical layer thickness of the individual layers can be approximately 30 to 90 nm, for example, approximately 50 nm. The layer stack can further contain one or two or more layers that are thicker than approximately 180 nm, for example, thicker than 200 nm.

For example, the reflector 120 can act as a resonator mirror and have a reflectivity of more than 95%, for example, 97% or more. Since the reflector 120 acts as a outcoupling mirror, the reflectivity is less than approximately 98%.

FIG. 1C shows a laser device 10 according to further embodiments. Deviating from embodiments that are illustrated in FIG. 1B, only one slanted reflective surface 122 is present here. For example, a reflective material 124 is applied on the slanted reflective surface 122. For example, the reflective material can comprise dielectric layers, metallic layers or a combination of dielectric and metallic layers. By adjusting the angle α between the slanted reflective surface 122 and a horizontal plane, the emission angle of the reflected radiation can be adjusted. For example, depending on the angle α, the reflected radiation can be reflected as first radiation 16 or as second radiation 17.

For example, the slanted reflective surface 122 can be produced using a slanted resist flank with mask erosion or by etching into the body 110 using grayscale lithography. According to further embodiments, the slanted reflective surface 122 can also be directly obliquely etched using ion beam etching.

For example, when using the laser device 10 in the photonic circuit 20 shown in FIG. 1A, depending on the design of the grating coupler 140, the laser device 10 can be configured such that the laser beam impinges directly perpendicularly on the grating coupler. Alternatively, the light can also impinge on the grating coupler 140 as second radiation 17 at an oblique angle. In this way, the coupling-in efficiency can be increased and back reflections can be suppressed.

According to embodiments, the laser device 10 can be implemented as a semiconductor laser. For example, the body 110 can be implemented as a semiconductor body, and the first part 111 of the body 110 can comprise a layer structure of an edge emitting semiconductor laser. For example, in this case, the second part 112 can also comprise the layer structure of an edge emitting semiconductor laser.

For example, as illustrated in FIG. 2, the semiconductor body 110 can comprise a substrate 130, for example a GaN substrate, another suitable semiconductor substrate or growth substrate for growing epitaxial layers. A first semiconductor layer 131 of a first conductivity type, an active zone 133 and a second semiconductor layer 132 of a second conductivity type, for example n-type, can be epitaxially grown over the substrate 130. The active zone 133 can comprise, for example, a pn-junction, a double heterostructure, a single quantum well structure (SQW) or a multi quantum well structure (MQW) for generating radiation. The term “quantum well structure” here does not have any sig-nificance with regard to the dimensionality of the quantization. It thus comprises, inter alia, quantum wells, quantum wires and quantum dots and any combination of these layers.

For example, the first and the second semiconductor layer 131, 132 can be GaN-based and be configured to emit electromagnetic radiation in the blue or UV range. However, other semiconductor materials and wavelength ranges are of course also possible. According to further embodiments, the chip can also be applied on a carrier, for example on a silicon substrate. For example, the first and the second semiconductor layer 131, 132 and the active zone 133 can be applied above a substrate 130 different from a growth substrate, for example a silicon substrate.

An optical resonator can be formed between the reflector 120, which acts as a first resonator mirror, and a second resonator mirror 121. The second resonator mirror 121 has a higher reflectivity than the reflector 120. For example, electrical connection regions for contacting the first semiconductor layer 131 or the second semiconductor layer 132 can be arranged in the region of the first main surface 134 of the semiconductor body 110. The first semiconductor layer 131, the second semiconductor layer 132 and the active zone 133 can form a semiconductor layer stack 135. As is illustrated in FIG. 1A, for example, the laser device 10 can be arranged above the circuit substrate 136 such that the first main surface 134 faces the circuit substrate 136. The semiconductor chip comprising the laser device 10 can be formed, for example, as a flip chip.

FIG. 3 shows a schematic top view of the photonic circuit 20, which is illustrated, for example, in FIG. 1A. In this case, for reasons of clarity, the position of the laser device 10 is in-dicated by dashed lines. As is illustrated in FIG. 3, contact regions 138 for contacting the first and the second semiconductor layer 131, 132 are applied in or above the circuit substrate 136. The contact regions 138 can be connected to the corresponding connection regions of the laser device 10 via bond pads 139, for example. For example, the laser device can be soldered directly onto the contact regions 138. Furthermore, the contact regions 138 can be connected to a current source or the like, for example. With such an implementation of the electrical contact, it is possible to electrically contact the laser device without additional process steps. A waveguide 137 made of a suitable material is arranged above or in the circuit substrate 136. Laser radiation emitted by the laser device 10 is coupled into the waveguide 137 via a coupling device, for example a grating coupler 140.

As has been described, the laser device 10 comprises a vertical sidewall including a reflector 120 to form a resonator. In ad-dition, the laser device 10 comprises a slanted reflective surface 122 by which emitted laser radiation 15 can be deflected in the direction of the waveguide 137. In this way, it is possible to use an edge-emitting laser 115 and simultaneously effect a direct vertical emission into the coupling device of the photonic circuit or array. The edge-emitting laser 115 usually provides a very good beam quality and is a single-mode laser. For example, in an implementation of the laser device as a flip chip or chip, the layer(s) of which face the waveguide 137 for beam generation, the laser device 10 can be integrated in a simple manner on the photonic circuit 20. Due to the fact that the laser radiation is coupled in via a grating coupler, no particularly high adjustment accuracy is required. By adjusting the angle of the slanted reflective surface, the coupling into the grating coupler 140 can be improved or back reflections can be reduced.

As has been described, a high-quality laser source, in particular an edge emitting laser 115, can be used and at the same time the emitted laser radiation can be coupled into the waveguide.

Although specific embodiments have been illustrated and described herein, persons skilled in the art will recognize that the specific embodiments shown and described can be replaced by a plurality of alternative and/or equivalent embodiments without departing from the scope of protection of the invention. The application is intended to cover any adaptations or variations of the specific embodiments discussed herein. Therefore, the invention is limited only by the claims and the equivalents thereof.

1. A laser device comprising:
a body comprising an edge emitting laser in a first part, the first part being patterned to form a vertical sidewall on an exit side of electromagnetic radiation, and the laser device comprising a reflector on the sidewall, wherein the body comprises, in a second part, a plurality of mutually parallel oblique ridges each having reflective surfaces each intersecting a vertical direction and a horizontal plane, wherein gaps between adjacent oblique ridges are unfilled, and the oblique reflective surfaces are configured to reflect radiation emitted by the edge emitting laser in a direction intersecting the horizontal plane, and
the first and second parts are spaced apart from each other.

2. The laser device according to claim 1, wherein, for a distance d between the plurality of mutually parallel oblique reflective surfaces, the following relationship holds:
$$0.7 * λ \leq d \leq 1.3 * λ ,$$
wherein λ is the wavelength of the laser radiation emitted by the edge emitting laser.

3. The laser device according to claim 1, further comprising a reflective material on the slanted reflective surface facing the edge emitting laser.

4. The laser device according to claim 1, wherein an inclination angle of the slanted reflective surface is selected according to an emission angle of the emitted laser radiation.

5. The laser device according to claim 1, wherein the body is a semiconductor body and the first part comprises a layer structure of an edge emitting semiconductor laser.

6. The laser device according to claim 5, wherein the semiconductor body comprises a substrate and a first semiconductor layer of a first conductivity type, an active zone and a second semiconductor layer of a second conductivity type in the first part,
wherein the first semiconductor layer, the active zone and the second semiconductor layer are arranged on top of each other on the substrate to form a semiconductor layer stack.

7. The laser device according to claim 1, wherein the reflector comprises a dielectric mirror.

8. A photonic circuit comprising a waveguide, a coupling device and a laser device, the laser device comprising:
a body comprising an edge emitting laser in a first part, the first part being patterned to form a vertical sidewall on an exit side of electromagnetic radiation, and the laser device comprising a reflector on the sidewall,
wherein the body comprises, in a second part, a plurality of mutually parallel oblique ridges each having reflective surfaces each intersecting a vertical direction and a horizontal plane, wherein gaps between adjacent oblique ridges are unfilled, and the oblique reflective surfaces are configured to reflect radiation emitted by the edge emitting laser in a direction intersecting the horizontal plane, and
the first and second parts are spaced apart from each other,
wherein the laser device is arranged vertically spaced apart from the waveguide and is configured to radiate electromagnetic radiation into the waveguide via the coupling device.

9. The photonic circuit according to claim 8, further comprising a circuit substrate, wherein the body is arranged vertically spaced apart from the circuit substrate and the waveguide is arranged in or on the circuit substrate.

10. The photonic circuit according to claim 9, further comprising contact regions for electrically contacting the laser device, wherein the contact regions are arranged in or on the circuit substrate.

11. A photonic arrangement comprising an optical fiber, a coupling device and a laser device, the laser device comprising:
a body comprising an edge emitting laser in a first part, the first part being patterned to form a vertical sidewall on an exit side of electromagnetic radiation, and the laser device comprising a reflector on the sidewall,
wherein the body comprises, in a second part, a plurality of mutually parallel oblique ridges each having reflective surfaces each intersecting a vertical direction and a horizontal plane, wherein gaps between adjacent oblique ridges are unfilled, and the oblique reflective surfaces are configured to reflect radiation emitted by the edge emitting laser in a direction intersecting the horizontal plane,
wherein the first and second parts are spaced apart from each other, and
wherein the laser device is arranged vertically spaced apart from the optical fiber and is configured to radiate electromagnetic radiation into the optical fiber via the coupling device.
